(19) United States
(12) Patent Application Publication
(10) Pub. No.: US 2026/0331607 A1
(43) Pub. Date: Oct. 22, 2026

(54) SYSTEM AND METHOD FOR PORTABLE POWER PACKS HAVING A UNIFORM DC ENVIRONMENT

(71) Applicant: Henry Burkhalter, Madison, MS (US)

(72) Inventor: Henry Burkhalter, Madison, MS (US)

(21) Appl. No.: 19/557,043

(22) Filed: Mar. 4, 2026

Related U.S. Application Data
(60) Provisional application No. 63/767,534, filed on Mar. 5, 2025.

(51) Int. Cl. H01M 10/46; G01R 31/367; G01R 31/371; G01R 31/382; G01R 31/392; H01M 10/42; H01M 10/44; H01M 10/613; H01M 10/623; H01M 50/247; H01M 50/507; H01M 50/512; H01M 50/516; H01M 50/517; H01M 50/522

(52) U.S. Cl. CPC H01M 10/46; G01R 31/367; G01R 31/371; G01R 31/382; G01R 31/392; H01M 10/425; H01M 10/441; H01M 10/613; H01M 10/623; H01M 50/247; H01M 50/507; H01M 50/512; H01M 50/516; H01M 50/517; H01M 50/522; H01M 2010/4271; H01M 2010/4278

(57) ABSTRACT

The present invention is directed to a portable battery pack connection scheme which provides a synchronized direct current (“DC”) environment for every battery unit in the pack. The connections within the present invention are be made via respective conductive paths each including a high-power DC precision cable segment and having a low resistance suitable to allow a high charge or discharge rate. In some embodiments of the present invention, there may be multiple rows of parallel-connected batteries arranged in a series to provide higher output voltage.

### CROSS REFERENCE TO RELATED APPLICATIONS

This application claims the priority benefit of U.S. Provisional Application Ser. No. 63/767,534, filed Mar. 5, 2025, the contents of which are incorporated herein by reference.

### BACKGROUND OF THE INVENTION

The present invention is directed to a portable battery pack connection scheme which provides a synchronized direct current (“DC”) environment for every battery unit in the pack. Typical portable battery packs are characterized by having more than one battery unit (herein referred to as a “cell,” “battery cell,” or “power cell”). Typical portable battery packs are often lacking in performance and do not offer the same advantages associated with individual cells. This is due in part to the fact that individual cells in a given pack often diverge from the pack average or target value during charge and discharge cycles, leading to diminished performance, operating characteristics, and overall life cycle. Thus, the overall performance of a portable battery pack is limited by the weakest cell or strongest cell during charge and discharge.

Furthermore, most battery packs require frequent conditioning cycles or an active management system in order to achieve acceptable performance. A conditioning cycle may be used to slowly bring the portable battery pack up to a full charge in order to equalize the state (i.e. to reduce the gap between the weakest and strongest cell) of the batteries in the pack. Active management, on the other hand, addresses the same issue by providing a small, localized charge or discharge across individual cells, thus keeping the strongest and weakest cells closer to the average. The overall result of active management is better pack performance, but this still fails to match the performance of an individual battery cell, as conditioning cycles are still required even when active management is employed.

A typical battery management system uses electronic devices such as thermistors or transistors in a series or in parallel with each cell in order to locally control the charge or discharge of the cell. Systems such as these typically dissipate extra power, limit pack capacity, and increase the expense of pack design and production. The present invention provides circuits and methods to combine battery cells in high power portable battery packs or power supply systems which improves capacity, charge and discharge rates, lifespan, and other performance characteristics.

### SUMMARY OF THE INVENTION

The present invention pertains to a system and method for precision portable battery pack units. In some embodiments of the present invention, a pack may have a positive load connection terminal and multiple batteries connected in parallel to the terminal. The connections may be made via respective conductive paths each including a high-power DC precision cable segment and having a low resistance suitable to allow a high charge or discharge rate. The precision cable segments are preferably made to be precisely matched in material, length, and cross section in order to have the same impedances or matching DC resistances. Connections and fittings to the battery terminals and to the positive load connection terminal are also preferably precision matched to each other. One or more additional parallel-connected sets of batteries may be connected in series with the previous set. The parallel connections are preferably made with matching conductors. In one preferred embodiment of the present invention, the conductive fittings and electrical busses are constructed using silver-plated soft copper, though other materials may be used.

In some embodiments of the present invention, a portable battery pack may have a positive load connection terminal connected to batteries with parallel conductive paths, each path having an under-load resistance differing from that of the other parallel conductive paths by less than approximately 1 milliohm. The pack may have low impedance precision DC cabling, and the under-load resistance may differ by less than approximately 5% or even 1% in some embodiments. The conductive paths may include cables and a respective conductive portion of a terminal bus. The cables may be connected to the terminal bus at equal spacing, in order to provide equal resistive paths between them. One such connection arrangement is done on a circular terminal bus having the positive load connection terminal coupled at its center. In some embodiments, the load series impedance of the batteries is as similar as possible, and the load series impedance of the parallel conductive paths is similar to or less than that of the batteries.

In some embodiments of the present invention, there may be multiple rows of parallel-connected batteries arranged in a series to provide higher output voltage. Similar parallel conductive arrangements may be made at the positive and negative ends of such a matrix. In order to allow for faster charging and discharging, the batteries may be low-impedance batteries. Some embodiments may employ high performance batteries having an open circuit resistance of about 1-2 milliohms. The batteries are preferably selected to have identical or near-identical electrical properties such as resistance, capacitance, induction, etc. External compression cages may be used to ensure that batteries conform their physical and electrical characteristics to a certain standard, or to prevent swelling of batteries that may deleteriously affect their chemistry. Capacitors or other suitable energy storage units (herein referred to as power cells) may be substituted for batteries in some embodiments. In some implementations, the circuit arrangement described herein may also connect active power supply circuits such as chargers or voltage supplies.

In other embodiments of the present invention, multiple battery cells may be connected in parallel to supply energy to a high-power load. The parallel connection is made with a precision conductive assembly being adapted to passively prevent voltage divergence of the multiple battery units. The precision conductive assembly may also be adapted to passively prevent battery capacity divergence. In some embodiments, the precision conductive assembly includes high power precision DC cables, in others it includes at least one busbar. In an alternative embodiment of the present invention, a portable battery pack comprising multiple means for storing energy, and a connection means for electrically connecting the multiple means for storing energy together and preventing discharge-rate divergence during use is provided.

Other aspects of the invention feature methods of mitigating battery characteristic divergence within a portable battery pack, including choosing multiple batteries having equal or near-equal load output resistance and charge acceptance characteristics; connecting the multiple batteries in parallel in a portable battery pack; charging the multiple batteries simultaneously after connecting the multiple batteries in parallel; maintaining equal charging voltages across each of the multiple batteries; and maintaining equal charge-acceptance rates in each of the multiple batteries. Another aspect includes discharging the multiple parallel-connected batteries simultaneously into a load; while discharging the multiple batteries simultaneously, maintaining equal discharging voltages across each of the multiple batteries; and while discharging the multiple batteries simultaneously; maintaining equal discharge currents in each of the multiple batteries.

Other features and aspects of the invention will become apparent from the following detailed description, taken in conjunction with the accompanying drawings, which illustrate, by way of example, the features in accordance with embodiments of the invention. The summary is not intended to limit the scope of the invention, which is defined solely by the claims attached hereto.

### BRIEF DESCRIPTION OF THE DRAWINGS

The various embodiments are illustrated by way of example, and not by way of limitation, in the figures of the accompanying drawings. Having thus described the invention in general terms, reference will now be made to the accompanying drawings, which are not necessarily drawn to scale, and wherein:

FIG. 1A shows a portable battery pack formed from two batteries connected in parallel using precision conductors.

FIG. 1B is a generalized circuit diagram of a portable battery pack according to another implementation.

FIG. 2 is a generalized circuit diagram of a portable battery pack according to another implementation.

FIGS. 3A and 3B are more detailed circuit diagrams of the buses shown in FIG. 2.

FIG. 4 is a circuit diagram of the 12-volt portable battery pack.

FIG. 5 illustrates an exemplary portable battery pack.

FIG. 6 illustrates an exemplary monitoring system of the present invention.

FIG. 7 illustrates several additional components which may be associated with the present invention.

### DETAILED DESCRIPTION OF THE PREFERRED EMBODIMENT

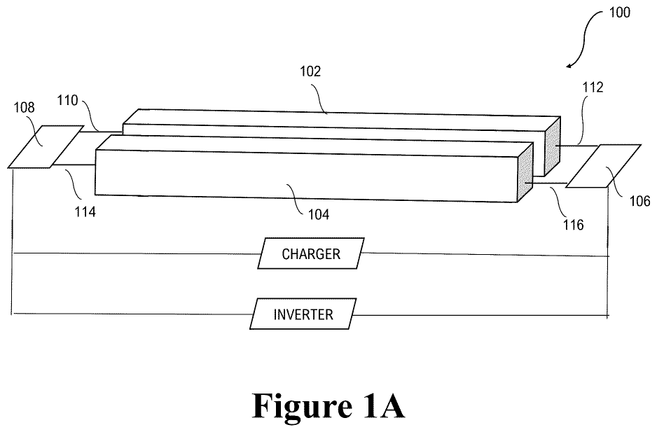

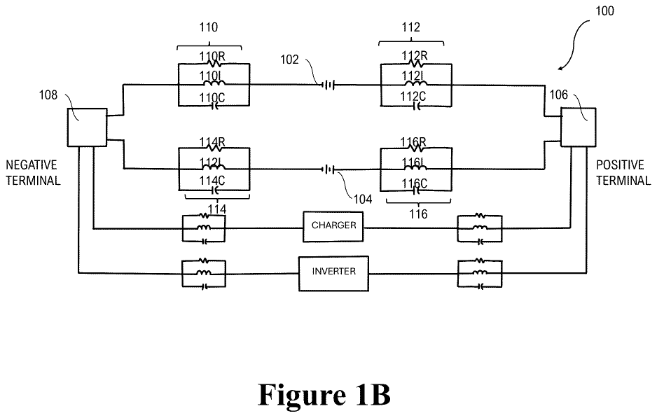

FIG. 1A shows a portable battery pack formed from two batteries connected in parallel using precision conductors. In accordance with the preferred embodiment of the present invention, a portable battery pack 100 may be comprised of batteries 102, 104, a positive terminal 106, a negative terminal 108, and cables 110, 112, 114, 116. The batteries 102, 104 may supply similar voltages and currents. The cables 110, 112, 114, 116 connect the batteries 102, 104 to the terminals 106, 108, in a parallel manner. In the preferred embodiment, the terminals 106, 108 supply the voltage and combined current to an external device. As a result, a device connected to the portable battery pack receives a voltage equivalent to that provided by a single battery and a current equal to the sum of the individual battery currents. Batteries 102, 104 may use the same chemistry (for example, and not by way of limitation, the batteries may use lithium, lead, nickel, or other suitable battery chemistries) and have the same dimensions, etc. As a result of their similar construction, the batteries 102, 104 may have identical or nearly identical voltage and current output curves when the same load is applied to each battery. “Identical” refers to materials, size, shape, and electrical properties such as the identical electrical resistance, capacitance, and inductance, unless otherwise stated.

In other embodiments, the cables 110, 112, 114, 116 are manufactured identically or near-identically to ensure they have similar electrical characteristics. In the preferred embodiment, the cables 110, 112 have characteristics identical or near-identical to each other, and in this or other embodiments, cables 114, 116 are identical or near-identical to each other and to cables 110, 112. If the loads applied to the two batteries are similar and the batteries themselves are similar, the batteries are expected to drain at the same rate and retain similar voltages. As a result, the batteries tend to be drained at a similar rate without the use, in this embodiment, of any active battery management systems or other active battery management circuitry present between batteries 102, 104, and the load terminals 106, 108. In the preferred embodiment, the cables 110, 112, 114, 116 are precision manufactured in order to reduce variability. In some instances, the cables 110, 112, 114, 116 may be manufactured from the same material, and may even be manufactured from the same piece of cabling to further reduce variability in wire looping, insulation, and other aspects.

FIG. 1B shows a circuit diagram of the portable battery pack shown in FIG. 1A. In accordance with the preferred embodiment of the present invention, the first cable 110, first battery 102, and second cable 112 form a parallel circuit with the third cable, 114, second battery 104, and fourth cable 116. Resistance, inductance, and capacitance is modeled for each cable. For example, the first cable 110 has a corresponding resistance 110R, inductance 110I, and capacitance 110C. In the depicted embodiment, the circuit branch consisting of cable 110, battery 102, and cable 112 is very similar and preferably identical to the branch consisting of cable 114, battery 104, and cable 116. The depicted cables 110, 112, 114, 116 are preferably DC cables, each comprising at least one high-power DC precision cable segment, preferably of the same length, material, cross section, and electrical characteristics and their length is preferably matched by precision measurement and cutting techniques to ensure accuracy.

The resistance of the cables and connections is preferably as low as possible. Further, the connections to each depicted battery terminal are also designed to be identical or near identical by carefully controlled soldering techniques in the attachment of connectors, as well as selecting electrically identical washers, bolts, plugs, prongs, or other electrical fittings. Such connections may create uniform parallel conductive paths from parallel-connected batteries 102, 104, to the output terminals 106, 108. For example, and not by way of limitation, each of the conductive portions shown is preferably identical or near identical. Where identical conductive portions are not possible or practical (for example, where non-flexible conductors of different lengths are needed to span different physical distances), then the electrical properties of the conductive portions are made to be as similar as possible.

Furthermore, the charger shown in FIG. 1B may be coupled to the conductive assembly and may be operable to charge the battery units from a power input. In some embodiments, the power supply module is a self-supporting moveable power pack. In the preferred embodiment, the charger is electrically connected to the positive and negative busbars. In the preferred embodiment, the circuit shown is located within a housing. Within the housing, the inverter is connected to the conductive assembly, the inverter presenting an AC voltage at an output connection terminal of the power pack, and connecting a charger to the housing, the charger operable to charge the multiple battery units from a power input.

The impedance of the high-power precision DC cables and the various connection fittings and solder connections that may be employed herein, is preferably as low as possible under existing design constraints. In one embodiment of the present invention, this is achieved by using fittings and busbars that are copper with silver plating, although other suitable low-resistance and low-loaded-inductance connections may be used. The silver-to-silver connections provide low impedance and low oxidation. The surface of the connections is preferably polished and processed with an oxidation inhibitor treatment to help ensure the extremely low resistance connections retain their characteristics for as long as possible. Other methods known in the art for ensuring low resistance may be used as well and are contemplated by the present invention. Further, preferred cables herein may be selected, for example, to work under a 50-amp current load. In some embodiments, high power DC cables are selected having a series resistance of preferably less than 2 milliohms underload. When expressed as a ratio of current to resistance (amps/ohms), this example provides 50,000/1 ratio at 1 milliohm, and a 25,000/1 ratio at 2 milliohms. These characteristics are plainly a high power, low resistance cable. Other low ratios, such as 20,000, 15,000, 10,000, and 1,000 or less may be considered high-power in certain applications. In embodiments using several parallel batteries, “high power” could mean each conductive path (each battery) provides 5 amps or 1 amp, for example, depending on how many batteries are in a pack. Connectors used herein may also be oversized to reduce their equivalent series resistance and enable such large currents without excessive power dissipation.

While FIGS. 1A-B depict uniform parallel conductive paths comprising cables and bolted electrical fittings, other embodiments may use any suitable conductive materials and fittings to form the parallel conductive paths, provided respective parallel paths are preferably identical or near identical. While precision matched length high-power DC cables comprise the parallel conductive paths, some embodiments contemplate solid busbars, traces, or other conductors which may be used if they are suitable. The properties achieved by employing matched precision cables may also be achieved in some embodiments by employing low resistance busbar designs, wherein each busbar section is identical and dimensionally equivalent, providing for identical resistance, capacitance, and inductance. Similarly, precision cables are typically cables where the resistance, capacitance, and inductance are known or equal to other precision cables of the same design and construction. The construction of a precision cable is made by manufacturing matched cable sets which are constructed from the same cable roll (lot) using copper connectors that are silvered, crimped and soldered using exactly the same process. Small variations in the manufacturing process can lead to large differences in the cables. The matched cables may be bench tested for consistency (or differences) before being put into a pack construction.

Resistance, inductance, and capacitance values for cable 110 may be very close to the corresponding values for cable 114, creating a synchronized DC environment from negative terminal 108 to the negative battery terminals of each of batteries 102, 104. Similarly, resistance, inductance, and capacitance values for cable 112 are very close to corresponding values for cable 116, creating a similar synchronized or uniform DC environment from positive terminal 106 to the positive battery terminals of each of batteries 102, 104. The batteries preferably have identical or near identical electrical characteristics. As a result, power draw from the batteries is similar if a load is placed on terminals 106, 108.

Under load, portable battery pack 100 provides a voltage and current output from terminals 106, 108. Since the electrical characteristics of the cables and batteries are similar or identical, the battery voltages are therefore identical or as close to identical as possible. If the battery voltages are similar, current does not flow from one battery to the other under loaded or unloaded conditions. When a load is connected, similar current is drawn from both batteries 102, 104, causing them to be discharged at a similar rate. Such similar discharge helps maintain the matched electrical characteristics of the batteries and prevent divergence of such characteristics. Specifically, during the discharge process, the connecting circuitry preferably maintains an equal discharge current from each battery, and an equal voltage, across each battery. Conversely, during the charging process, the connecting circuitry maintains an equal charge current to each battery and an equal voltage across each battery. The depicted circuit in FIG. 1B operates passively to match the DC current and voltage at the output terminals of batteries 102, 104, which may be described as providing a synchronized DC environment which may be used to passively prevent divergence of battery performance characteristics, under discharge (load pack) and charge (charging pack) conditions.

In some embodiments, the portable battery pack 100 is rechargeable. Since the two branches of the circuit are identical or similar, half of an applied charge is deposited in each battery. While the portable battery pack 100 is being charged, the batteries 102, 104 may be charged at an equal rate such that, at any given time, the batteries 102, 104 have approximately the same amount of stored charge, thus maintaining the similarity of their electrical characteristics such as voltage, capacity, charge acceptance rate, and temperature, which may be maintained at an ideal level via cooling methods such as liquid or air cooling.

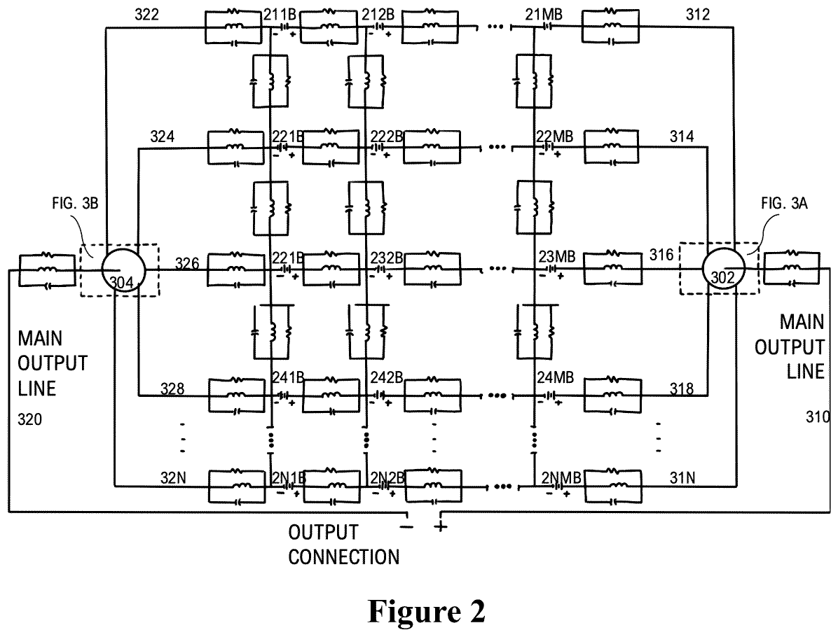

FIG. 2 is a generalized circuit diagram 200 of a portable battery pack. According to the preferred embodiment of the present invention, an array of batteries 211B-2NMB are connected with precision conductors each represented by a resistor, inductor, and capacitor as shown. The array of batteries are connected in series or parallel by the precision conductors. The array may provide or store electric power via an external interface. Particularly, arrangements with many parallel batteries result in higher current capacity than a single row, whereas arrangements with many batteries in series provide a higher voltage.

The depicted circuit 200 has an array of batteries and conductors. For the battery reference numbers in FIG. 2, the first digit of the reference number may indicate the Figure number, the second digit may indicate a row position, and the third digit may indicate a column position with “N” and “M” corresponding to the final row or column in an array with N rows and M columns of batteries. Reference numbers ending with a “B” refer to a battery.

The batteries in the circuit 200 should be of a similar type. For example, and not by way of limitation, the batteries should have the same chemistry and physical construction. In some embodiments, the batteries may be of a standardized lead-acid type, capable of high-power output. Other battery types may be employed, including lithium, nickel metal hydride, absorbent glass mat (“AGM”), nickel-cadmium, flow, alkaline, zinc-air, complementary metal oxide semiconductor (“CMOS”), and other batteries. As a result of similar chemistry and construction, the batteries should have similar electrical characteristics. For instance, the batteries may provide similar currents at a similar voltage when an identical load is applied across their positive and negative terminals.

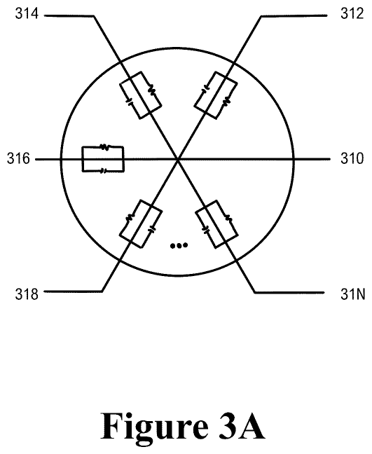

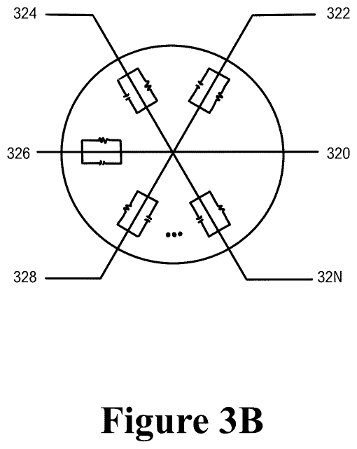

The batteries in the depicted array are connected in series using precision conductors. A set of batteries are connected in series if the positive terminal of one battery is connected to the negative terminal of another battery. The output voltage of a series circuit is equal to the sum of voltages of the batteries that are in series. The batteries in circuit 200 may be connected in parallel using precision conductors. The current capacity of the system increases with the number of parallel branches. For example, a circuit with four parallel branches will have twice the current capacity of a circuit with two parallel branches. Precision conductors may be modeled by a resistor, an inductor, and a capacitor, wherein each inductor, and capacitor in FIGS. 2 and 3A-B corresponds to the resistance, inductance, and capacitance of the electrical path, for example and not by way of limitation, a conductor that directly connects two elements in the circuit 200.

Within the circuit 200, columns represent batteries connected in parallel, and for the batteries connected in parallel, it may be desirable to ensure that the current flowing through each battery is similar in order to ensure that the batteries have similar performance curves. When a battery is discharged, its internal resistance, voltage, current capacity, etc. may change. If one battery in a parallel circuit discharges at a different rate than another battery in the same circuit, a current will flow between them which will reduce the amount of current available to the circuit's output. To avoid this issue during the discharge process, the depicted connecting circuitry should maintain an equal discharge current from each battery, and an equal voltage across each battery. Conversely, during the charging process, the connecting circuitry should maintain an equal charge current to each battery and an equal voltage across each battery. Further, because the battery characteristics are kept identical or near-identical, the charge-acceptance rates of the batteries are maintained as equal.

Combining the parallel connection scheme with low-impedance batteries and low-impedance conductors provides an ability to charge and discharge at very fast rates. For example, and not by way of limitation, some preferred embodiments have such low series resistance values for the entire pack that it may be charged from 30% to 85% capacity in 15 minutes. This represents well over a C1 charge rate. Many preferred embodiments may charge at a C1 charge rate, a 2×C1 charge rate, a 3×C1 charge rate, or even 4×C1 charge rate. Some embodiments of the various portable pack designs herein charge at 1000 amp maximum charge rate with 500 or 600 amps being typical. In order to achieve this, the present invention may implement the use of low impedance batteries, combined in parallel. This combination divides the series impedance of each battery (or series line of batteries) by the number of parallel connections, thus drastically reducing the series impedance of the pack and increasing the maximum charge rate. Such a maximum charge rate may be employed to implement a pulse charging scheme, for example, or other charging schemes including constant current charging.

In accordance with the preferred embodiment of the present invention, conductors linking batteries in series within adjacent columns in FIG. 2 have identical or near identical electrical characteristics. In some embodiments, all the conductors linking two columns of batteries may have a nearly identical resistance. For example, the resistances of all the conductors linking the first two battery columns may be the same 1%. For some applications, a 5% tolerance is considered acceptable, but for other applications (typically larger arrays) a 1% or 0.1% tolerance is preferred. In some embodiments, all the conductors linking two columns of batteries may have near identical inductance. For instance, the inductances of all the conductors linking the first two battery columns may be the same within 0.1% or less. Larger arrays of batteries preferably have smaller tolerances. In some embodiments, all the conductors linking two columns of batteries may have near identical capacitance. For example, the capacitance of all the conductors linking the first two battery columns may be the same within 1%. The similarity of impedance values may apply to operating (under load) characteristics as well as to open circuit characteristics.

Circuits which have batteries in both series and parallel may provide multiple, simultaneous paths for current flow. To ensure that charging and discharge from the batteries in the circuit occur at a similar rate, it may be desirable to control the electrical characteristics of each conductor in the battery array such that they are identical within a small tolerance, for example, and not by way of limitation, a tolerance of 0.1% or 1%.

Precision conductors may be made to have similar characteristics by tightly controlling manufacturing variation. A single batch of material may be used to create a matched set of conductors/in practice, the precision conductors may be wires, cables, solid conductors, etc. In some embodiments, a single spool of cable may be used to manufacture a set of matched conductors.

Batteries on the vertical edge of the depicted array of FIG. 2 may be linked to main output lines. Conductors 312-31N link each battery 21MB-2NMB on the positive edge of the array to a positive bus 302. Conductors 322-32N link each battery 211B-2N1B on the negative edge of the array to a negative bus. The conductors 322-32N also have identical or near identical electrical characteristics to ensure that the circuit paths between each of the batteries and busses 302, 304 are as identical as possible. The conductors 312-31N are similarly identical to each other and may be identical to conductors 322-32N. By maintaining similarity across all conductors of the array, an identical or similar voltage level at the positive terminal of each battery in the top-level (highest voltage potential) column of batteries may be achieved.

FIGS. 3A-B are more detailed circuit diagrams of the buses 302, 304 shown in FIG. 2. The output busses 302, 304 in this embodiment are designed to have conductive paths with similar electrical characteristics as seen from the output lines 310, 320. For example, and not by way of limitation, the row conductors 312-31N are linked to the positive main output line 310 in a manner that facilitates similar conductive paths from the terminals of the positive bus 302. In some embodiments, the positive row conductors 312-31N may be joined to bus 302 in a radially symmetric fashion, conductors 322-32N on the negative edge of the battery array may be connected via bus 304 to negative main output line 320. The electrical characteristics of each path between the row conductors at the edge of the battery array and the main output lines 310, 320, may be modeled by a resistor, an inductor, and a capacitor.

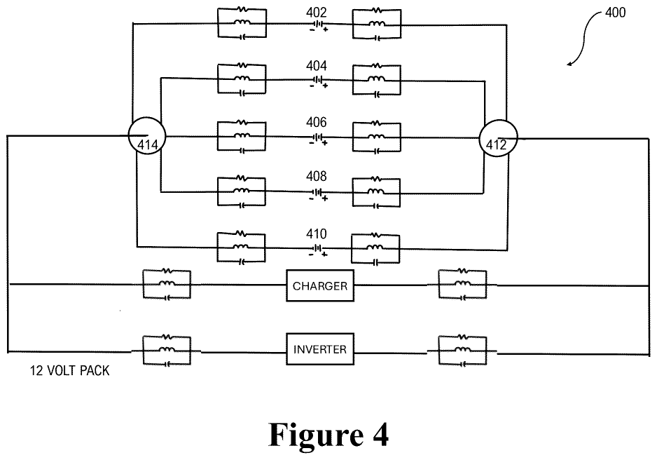

FIG. 4 is a circuit diagram of a 12-volt portable battery pack. In accordance with the preferred embodiment of the present invention, the portable battery pack 400 implements a version of the circuit described in FIG. 2. In this case, a single column of five 12-volt power cells 402-410 are used such that no power cells are in series. Furthermore, the charger shown in FIG. 4 may be coupled to the conductive assembly and may be operable to charge the battery units from a power input. In some embodiments, the power supply module is a self-supporting moveable power pack. In the preferred embodiment, the charge is electrically connected to the positive and negative busbars. In the preferred embodiment, the circuit shown is located within a housing. Within the housing, the inverter is connected to the conductive assembly, the inverter presenting an AC voltage at an output connection terminal of the power pack, and connecting a charger to the housing, the charger operable to charge the multiple battery units from a power input.

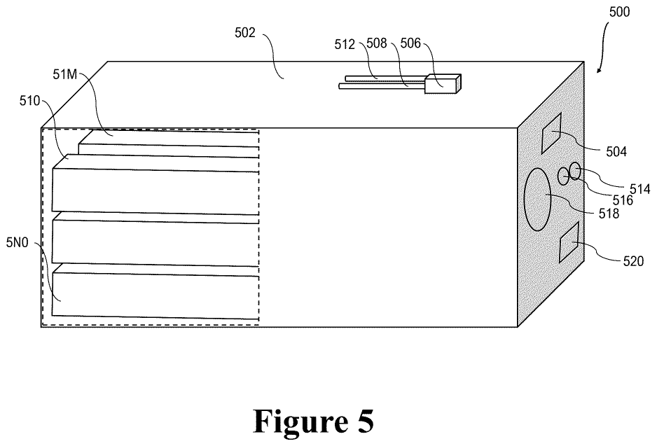

FIG. 5 shows an exemplary outer casing for a portable battery pack. In accordance with the preferred embodiment, the portable battery pack case 500 may be comprised of a casing 502, a battery monitoring system 504, an output connector 506, a negative output cable 508 and positive output cable 510, a VDC power outlet 514, a power switch 516, a vent fan 518, and an Anderson connector 520. The battery casing may be constructed from steel, aluminum, hard plastics, foams, various types of composites, or other suitable materials. The power cells contained within the case 502 may be arranged in any suitable formation. The portable battery pack may contain high-performance power cells arranged as shown in FIG. 1A, FIGS. 5A-B, or other suitable arrangements. The power cells may be arranged in both parallel and in series, or one or the other.

The power cells of the present invention are capable of storing and releasing electrical energy. The power cells all have similar electrical characteristics, such as similar voltage and current curves during charge and discharge cycles. Similarly, the precision cables, precision interconnect ladder and power buses preferably have uniform electrical characteristics, such as resistance, inductance, and capacitance, to ensure that the current passing through each power cell is identical or near identical. This uniformity may be achieved by controlling design, materials, and manufacturing. In this embodiment, each power cell is connected to all other power cells via the precision interconnect ladder and power buses.

While circular and straight busbars are used in some embodiments herein, other implementations may use other connection strategies to provide the desired matching parallel connections, or match is a closely as possible using that particular strategy. For example, Anderson connectors may be used, instead of a circular power bus, to couple the multiple parallel precision cables together to a common power lead.

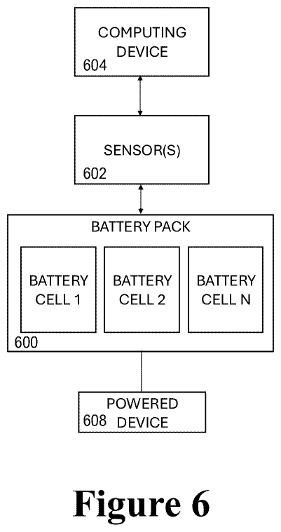

FIG. 6 illustrates an exemplary monitoring system of the present invention. In accordance with the preferred embodiment of the present invention, at least one sensor 602 may be associated with a portable battery pack 600. Sensor 602 may be in communication with a computing device 604, which may be configured to receive data collected via sensor 602 and analyze the data in order to determine a state of the portable battery pack 600 while portable battery pack 600 provides power to a powered device 608. Monitoring via sensor 602 may also occur while no powered device 608 is connected to portable battery pack 600. Portable battery pack 600 may have N battery cells contained within, which may be maintained in a uniform DC environment as described above. The sensor(s) 602 may be configured to detect changes in, for example, and not by means of limitation, amplitude, temperature, overall battery health, or other parameters associated with portable battery pack 600. Computing device 604 may be configured to compile a battery health report which may be accessed by a user.

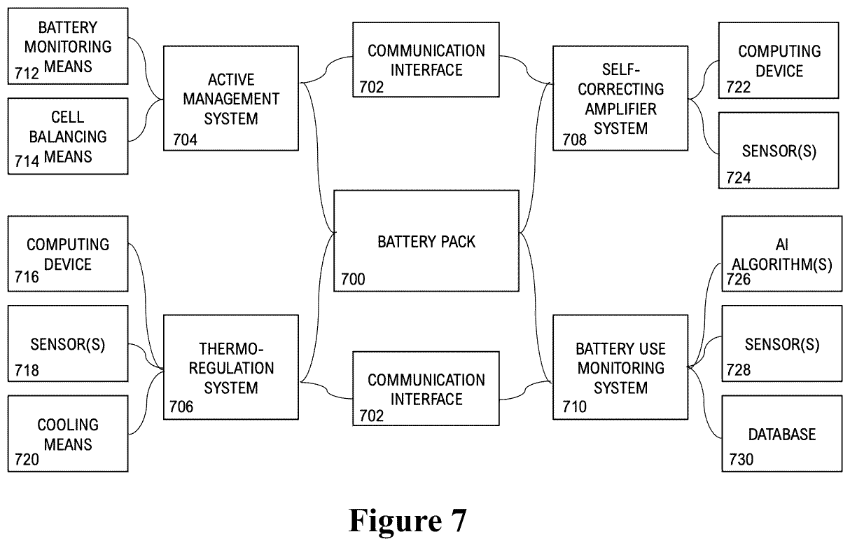

FIG. 7 illustrates several additional components which may be associated with the present invention. In accordance with the preferred embodiment of the present invention, a portable battery pack 700 may be associated with an active management system 704, a thermoregulation system 706, a battery use monitoring system 710, and a self-correcting amplifier system 708. These systems 704-710 may be associated with a communication interface 702. The active management system 704 may be associated with battery monitoring means 712, which may comprise a plurality of sensors or other methods known and used to monitor the portable battery pack 700. The battery management system may further integrate cell balancing means 714. Other active battery management systems may also be associated with the system.

The thermoregulation system 706 may comprise a computing device 716, at least one sensor 718, and cooling means 720. A computing device 716 may be a computer or other similar device and may comprise a system of processors, memory, and other computer systems. Computing device 716 may be the same as or different from computing device 722. The sensor(s) 718 may be configured to detect changes in temperature of the portable battery pack 700 and communicate any detected changes to the computing device 716, which may in turn provide instructions to cooling means 720. Cooling means 720 may comprise liquid cooling means, such as ethylene-glycol-based solutions, or air-cooling means, such as at least one fan.

The self-correcting amplifier system 708 may be associated with at least one sensor 724 and at least one computing device 722, which may be the same as or different from computing device 716. The self-correcting amplifier system may be employed in order to detect and correct any offset in voltage from portable battery pack 700 in order to increase efficiency.

The battery use monitoring system 710 may be associated with at least one sensor 728, at least one database 730, and an artificial intelligence (“AI”) algorithm 726 configured to learn battery use patterns associated with portable battery pack 700 and analyze the patterns to optimize usage. The battery use monitoring system 710 may be configured to detect patterns or changes to typical usage of portable battery pack 700. Battery use monitoring system 710, self-correcting amplifier system 708, thermoregulation system 706, and active management system 704 may be configured to communicate with a communication interface 702. Communication interface 702 may provide information and data collected from the systems 704-710 to a user in the form of battery health reports and analytics. Any relevant information regarding overall battery health and electrical characteristics including charge acceptance rate, capacity, and other factors may be reported via communication interface 702.

While various embodiments of the disclosed technology have been described above, it should be understood that they have been presented by way of example only, and not of limitation. Likewise, the various diagrams may depict an example architectural or other configuration for the disclosed technology, which is done to aid in understanding the features and functionality that may be included in the disclosed technology. The disclosed technology is not restricted to the illustrated example architectures or configurations, but the desired features may be implemented using a variety of alternative architectures and configurations. Indeed, it will be apparent to one of skill in the art how alternative functional, logical or physical partitioning and configurations may be implemented to implement the desired features of the technology disclosed herein. Also, a multitude of different constituent module names other than those depicted herein may be applied to the various partitions. Additionally, with regard to flow diagrams, operational descriptions and method claims, the order in which the steps are presented herein shall not mandate that various embodiments be implemented to perform the recited functionality in the same order unless the context dictates otherwise.

Although the disclosed technology is described above in terms of various exemplary embodiments and implementations, it should be understood that the various features, aspects and functionality described in one or more of the individual embodiments are not limited in their applicability to the particular embodiment with which they are described, but instead may be applied, alone or in various combinations, to one or more of the other embodiments of the disclosed technology, whether or not such embodiments are described and whether or not such features are presented as being a part of a described embodiment. Thus, the breadth and scope of the technology disclosed herein should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

What is claimed is:

1. A portable precision battery pack system for connecting and discharging a plurality of battery cells in parallel, the system comprising:
a portable housing;
a plurality of battery cells disposed within said housing;
a positive bus and a negative bus disposed within said housing;
a positive load connection terminal and a negative load connection terminal;
a plurality of parallel conductive paths connecting said plurality of battery cells to said positive and negative load connection terminals through said positive and negative bus, each conductive path comprising at least one high-power direct current (DC) precision conductive segment;
wherein said high-power DC precision conductive segment is configured to have a predetermined resistance enabling charge and discharge rate while maintaining low impedance;
wherein each parallel conductive path is physically and electrically matched to one another by at least one of material, length, cross-sectional area, spacing, or impedance characteristics;
a plurality of connections and fittings configured to connect to battery terminals and said load connection terminals;
wherein said plurality of connections and fittings are impedance-matched to one another;
a charger electrically coupled to said positive and negative buses; and
a battery monitoring system disposed within said housing;
wherein said battery monitoring system comprises at least one sensor and a computing device configured to detect operating parameters and determine a state of said portable battery pack.

2. The system of claim 1, wherein said cables are connected to said terminal buses at an equal spacing to provide equal resistive paths between them.

3. The system of claim 1, wherein under-load resistance of each parallel conductive path differs from other parallel conductive paths by less than 1 milliohm.

4. The system of claim 1, further comprising one or more additional parallel-connected sets of batteries connected in series with a previous set.

5. The system of claim 1, wherein conductive fittings and electrical buses are constructed using silver-plated soft copper.

6. The system of claim 1, wherein high-power DC precision cable segments are manufactured from the same material or same piece of cabling.

7. The system of claim 1, wherein said plurality of connections are oversized to reduce their equivalent series resistance and enable large currents without excessive power dissipation.

8. The system of claim 1, wherein high-power DC precision cables are substituted by at least one of: solid busbars, conductive traces, or discrete conductors.

9. The system of claim 1, further comprising other suitable low-resistance and low-loaded inductance connections.

10. A method of constructing a portable precision battery pack to improve capacity, charge and discharge rates, lifespan, and performance, the method comprising:
connecting a plurality of battery units in parallel to a positive and negative bus;
mitigating battery characteristic divergence within said portable battery pack by at least one of:
selecting batteries having substantially equal load output resistance and charge acceptance characteristics;
charging said plurality of battery units simultaneously after connecting said plurality of battery units in parallel;
maintaining equal charging voltages across each battery unit of said plurality of battery units; and
maintaining equal charge-acceptance rates in each battery unit of said plurality of battery units;
discharging said plurality of battery units in parallel simultaneously into a load;
wherein during discharge, equal discharging voltages and currents across each battery unit of said plurality of battery units is maintained by simultaneous operation;
passively matching DC current and voltage at output terminals of said plurality of battery units to prevent divergence of battery performance characteristics under discharge and charge conditions; and
charging each battery unit of said plurality of battery units at an equal rate by depositing applied charge equally among all battery units across a plurality of circuit branches of said portable battery pack.

11. The method of claim 10, wherein said parallel connections includes at least one busbar.

12. The method of claim 10, wherein each busbar section is identical and dimensionally equivalent.

13. The method of claim 10, wherein low impedance is maintained by using fittings and busbars that are copper with silver plating.

14. The method of claim 10, wherein low impedance is further maintained by polishing a treating a connection surface with an oxidation inhibitor.

15. A portable precision battery pack system for connecting and discharging a plurality of battery cells in parallel, the system comprising:
a portable housing;
an array of battery cells connected with precision conductors;
wherein said array of batteries comprises:
a plurality of cable-battery-cable circuit branch configurations comprising:
a first cable;
a first battery;
a second cable;
a third cable;
wherein said second cable forms a parallel circuit with said third cable;
a second battery; and
a fourth cable;
a plurality of conductors linking positive and negative edges of said array to a positive bus and negative bus;
a plurality of conductive interconnections with minimized resistance and substantially identical physical and electrical properties;
a plurality of uniform parallel conductive paths connecting said battery cells to output terminals;
a plurality of output buses with substantially equal electrical characteristics;
a charger coupled to said plurality of output buses via an inverter configured to present AC voltage at an output terminal;
a plurality of output connectors comprising a VDC outlet, Anderson connector, power switch, and vent fan;
at least one of:
a battery monitoring system comprising:
at least one sensor;
a computing device configured to:
receive and analyze sensor data;
determine a state of said portable battery pack; and
interface with remote monitoring devices;
wherein said computing device can operate while no powered device is connected;
an active management system;
a thermoregulation system comprising at least one cooling mechanism; and
a self-correcting amplifier system.

16. The system of claim 15, wherein said plurality of conductive interconnections are made to be substantially identical to one another by carefully controlled soldering techniques and a selection of electrically identical washers, bolts, plugs, prongs, and other electrical fittings.

17. The system of claim 15, wherein said portable battery pack is rechargeable.

18. The system of claim 15, wherein said portable battery pack housing is constructed from at least one of: steel, aluminum, hard plastics, foams, various types of compotes, or any combination thereof.

19. The system of claim 15, wherein said computing device generates a battery health report accessible by a user.

20. The system of claim 15, wherein said battery monitoring system further comprises a machine learning algorithm configured to learn battery usage patterns and optimize battery operation.
